(19) United States
(12) Patent Application Publication
(10) Pub. No.: US 2012/0025369 A1
(43) Pub. Date: Feb. 2, 2012

(54) SEMICONDUCTOR PACKAGE

(76) Inventors: Chung-Yao KAO, Kaohsiung City (TW); Yu-Ju Li, Niaosong Township (TW); Shih-Hung Huang, Kaohsiung City (TW); Chen-Ming Lai, Tainan City (TW)

(21) Appl. No.: 12/947,136

(22) Filed: Nov. 16, 2010

(30) Foreign Application Priority Data
Aug. 2, 2010 (TW) 99125650

(51) Int. Cl. H01L 23/498

(52) U.S. Cl. 257/737; 257/E23.068

(57) ABSTRACT

A semiconductor package is provided. The semiconductor package includes a substrate, a semiconductor element, a plurality of element contacts and a molding compound. The substrate includes a passivation layer and a plurality of substrate pads. Each substrate pad includes a protrusion and an embedded portion. The embedded portion is embedded in the passivation layer, and the protrusion projects from the passivation layer. The semiconductor element includes a plurality of under bump metallurgies (UBM) with recesses. The ratio of the width of each recess to the first width of the protrusion is larger than 1. The element contacts connect the UBM and the substrate pads. The molding compound covers the semiconductor element.

This application claims the benefit of Taiwan application Serial No. 99125650, filed Aug. 2, 2010, the subject matter of which is incorporated herein by reference.

### BACKGROUND OF THE INVENTION

1. Field of the Invention

The invention relates in general to a semiconductor package, and more particularly to a flip-chip chip scale package (FCCSP) semiconductor package.

2. Description of the Related Art

A conventional semiconductor package includes a substrate, a flip chip and a molding compound. The molding compound contains a certain ratio of fillers and covers the semiconductor package. The space between the flip chip and the substrate is filled for fixing the solder ball of the flip chip, so that the flip chip is steady bonded on the substrate.

The substrate includes a plurality of pads and a passivation layer. The passivation layer has a plurality of apertures that expose the pads. In general, based on the structural difference between the pad and the passivation layer, the design of the semiconductor package is divided into solder mask defined (SMD) semiconductor package and non-solder mask defined (NSMD) semiconductor package. No matter which one of these two packages, the pads are lower than the upper surface of the passivation layer and a portion of the solder ball of the flip chip is embedded into the aperture. It causes the gap between the passivation layer and the flip chip to be too small for molding process. The flow of the liquid molding compound stagnates, the filling quality is poor, and the fillers of the molding compound cannot enter the gap smoothly.

### SUMMARY OF THE INVENTION

The invention relates to a semiconductor package. The molding compound smoothly flows between the semiconductor element and the substrate of the semiconductor package, and the fillers within the more varieties of the molding compound can enter the gap between the semiconductor element and the substrate, making the selection of the molding compound more flexible.

According to a first aspect of the present invention, a semiconductor package is provided. The semiconductor package includes a substrate, a semiconductor element, a plurality of element contacts and a molding compound. The substrate includes a passivation layer and a plurality of substrate pads. Each substrate pad includes a protrusion and an embedded portion. The embedded portion is embedded in the passivation layer, and the protrusion projects from the passivation layer. The semiconductor element includes a plurality of under bump metallurgies (UBM) with recesses. The ratio of the width of each recess to the first width of the protrusion is larger than 1. The element contacts connect the UBM and the substrate pads. The molding compound covers the semiconductor element.

The invention will become apparent from the following detailed description of the preferred but non-limiting embodiments. The following description is made with reference to the accompanying drawings.

### BRIEF DESCRIPTION OF THE DRAWINGS

FIG. 1 shows a cross-sectional view of a semiconductor package according to a embodiment of the invention; and

FIG. 2 shows a cross-sectional view of the semiconductor package of FIG. 1 before the semiconductor element and the substrate are combined.

### DETAILED DESCRIPTION OF THE INVENTION

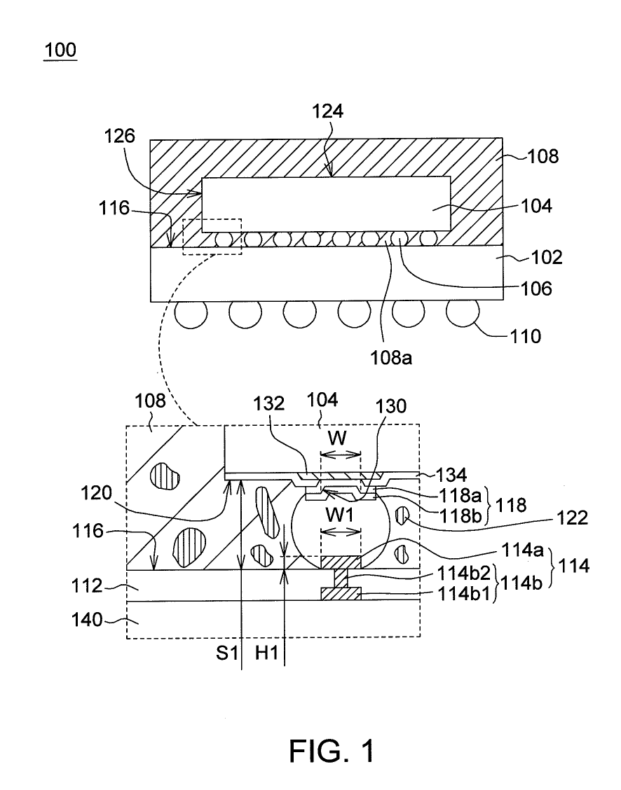

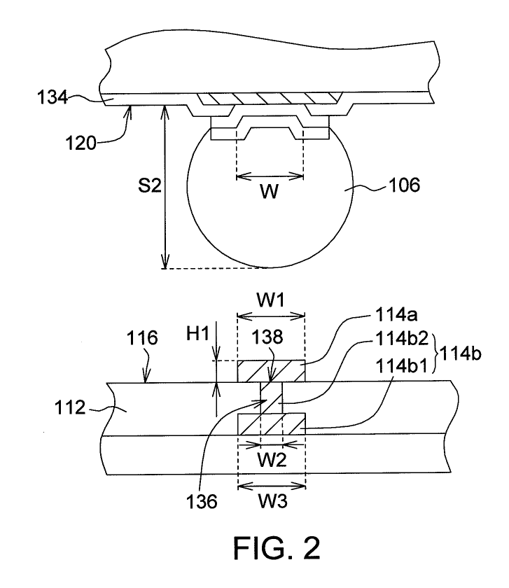

Referring to FIG. 1 and FIG. 2. FIG. 1 is a cross-sectional view of a semiconductor package according to an embodiment of the invention. FIG. 2 is a cross-sectional view of the semiconductor package of FIG. 1 before the semiconductor element and the substrate are combined. As depicted in FIG. 1, the semiconductor package 100, such as a flip-chip chip scale package (FCCSP), includes a substrate 102, a semiconductor element 104, a plurality of element contacts 106, a molding compound 108 and a plurality of substrate contacts 110. The substrate contacts 110, such as solder balls, electrically connect an external circuit and the semiconductor package 100. The molding compound 108 contains fillers 122 whose maximum size preferably ranges from 18 to 23 micrometers (μm).

The substrate 102 includes a base 140, a substrate passivation layer 112 and a plurality of substrate pads 114. The substrate passivation layer 112, such as a solder mask, is disposed on the base 140. The substrate pad 114, made from copper, can be formed by electroplating technology. The substrate pad 114 includes a protrusion 114a and an embedded portion 114b. The embedded portion 114b is embedded in the substrate passivation layer 112, and the protrusion 114a projects from the substrate passivation layer 112. The molding compound 108 covers an upper surface 124 and a lateral side 126 of the semiconductor element 104, and a portion 108a of the molding compound 108 is interposed between the semiconductor element 104 and the substrate 102.

The semiconductor element 104, such as a flip chip, includes a plurality of element pads 132 (only one element pad is illustrated in FIG. 1), an element passivation layer 134, and a plurality of under bump metallurgies (UBM) 118. The element passivation layer 134 covers a portion of the element pads 132, and exposes another portion of the element pads 132. The element contacts 106, such as solder balls, bumps, copper pillars and combinations of several conducting materials, electrically connect the UBM 118 and the substrate pad 114.

The UBM 118 of the semiconductor element 104 is disposed on the protrusion 114a of the substrate 102 via the element contact 106. The protrusion 114a, projecting from the upper surface 116 of the substrate passivation layer 112, increases the distance S1 between the upper surface 116 of the substrate passivation layer 112 and the lower surface 120 of the element passivation layer 134 of the semiconductor element 104. The distance S1 is larger than the maximum size of the fillers 122. Preferably, the difference between the distance S1 and the size of the maximum fillers 122 is equal to or larger than 5 μm. Under such circumstance, the large-sized fillers 122 can enter the gap between the upper surface 116 of the substrate passivation layer 112 and the lower surface 120 of the semiconductor element 104, thus the applicable varieties of the molding compound for packaging the semiconductor element 104 are increased and the selectivity of the molding compound 108 becomes more flexible.

Compared with the conventional design of disposing the underfill material between the semiconductor element and the substrate, in the present embodiment of the invention, the distance S1 between the upper surface 116 of the substrate passivation layer 112 and the lower surface 120 of the semiconductor element 104 is increased. Accordingly, the molding compound 108 in liquid state can smoothly flow into the gap between the upper surface 116 and the lower surface 120 during the molding process. Therefore, the filling quality of the molding compound 108 between the substrate 102 and the semiconductor element 104 is improved, and there is no need to interpose costly underfill material.

In addition, each UBM 118 includes an inner-layer structure 118a and an outer-layer structure 118b which are mutually connected. The inner-layer structures 118a is correspondingly disposed on the substrate pads 114. The inner-layer structure 118a defines a recess 130. Preferably but not limited, the ratio of the width W of the recess 130 to the first width W1 of the protrusion 114a is larger than or substantially equal to 1, and preferably is larger than or equal to 1.2, so that the UBM 118 can be more steady disposed on the substrate pad 114. The structural strength and reliability of the UBM 118 are enhanced for withstanding higher shear stress in order to prevent the UBM 118 from being delaminated from the substrate pad 114.

When the ratio of the width W of the recess 130 to the first width W1 of the protrusion 114a is larger than or substantially equal to 1, the element contacts 106 contact the entire exposed outer surface of the protrusion 114a; hence, the quality of electrical connection between the element contacts 106 and the protrusion 114a is increased. Preferably, the element contacts 106 substantially cover the protrusion 114a but contact the substrate passivation layer 112 as less as possible, so that more material of the element contacts 106 can be used for elevating the semiconductor element 104 to increase the distance S1 between the upper surface 116 of the substrate passivation layer 112 and the lower surface 120 of the semiconductor element 104.

Preferably but not limited, the element contacts 106 at most cover the outer-layer structure 118b and the protrusion 114a as depicted in FIG. 1 for elevating the semiconductor element 104 as much as possible.

As depicted in FIG. 2, an aperture 136 and an opening 138 corresponding to the aperture 136 are defined by the substrate passivation layer 112. The entire aperture 136 is filled with the embedded portion 114b, wherein the second width W2 of the connection portion 114b2 is substantially equal to the diameter of the opening 138.

The embedded portion 114b includes a bottom portion 114b1 and a connection portion 114b2. The connection portion 114b2 connects the protrusion 114a and bottom portion 114b1. Preferably but not limited, the ratio of the first width W1 of the protrusion 114a to the second width W2 of the connection portion 114b2 ranges from 0.3 to 1.5. In the present embodiment of the invention, the protrusion 114a, the connection portion 114b2 and bottom portion 114b1 form an I-shaped structure, so that the contact area between the embedded portion 114b and the substrate passivation layer 112 is increased, and the substrate passivation layer 112 can more steady cover the embedded portion 114b. Or, in another embodiment, if the second width W2 is larger than the first width W1 and the third width W3 of the bottom portion 114b1, then similar covering effect can be achieved. Or, in another embodiment, the second width W2, the first width W1 and the third width W3 are substantially identical.

In addition, the ratio of the height H1 of the protrusion 114a to the distance S1 is smaller than or substantially equal to 0.5. That is, the distance S1 can be larger than two times of the height H1 of the protrusion 114a. Wherein, the height H1 is smaller than 25 μm, but such exemplification is not for limiting the invention.

As depicted in FIG. 2, the distance S2 between the element contact 106 and the lower surface 120 of the element passivation layer 134 is about 90 μm, and the height H1 of the protrusion 114a is about 15 μm. Owing to the design of the protrusion 114a, the distance S1 between the upper surface 116 of the substrate passivation layer 112 and the lower surface 120 of the semiconductor element 104 is larger than 80 μm, and more varieties of the fillers in the molding compound can enter the gap between the upper surface 116 and the lower surface 120. However, the above embodiment is not for limiting the invention, and in other embodiments, the design of the distance S1 is dependent on actual needs.

Further, referring to FIG. 1, compared to the design of a conventional semiconductor package, in the present embodiment of the invention, the element contact 106 is disposed on the protrusion 114a, so that the entire element contact 106 is above the upper surface 116 of the substrate passivation layer 112, and a larger distance S1 is achieved by elevating the semiconductor element 104.

According to the semiconductor package disclosed in the above embodiments of the invention, the element contact projects from the upper surface of the substrate passivation layer. Thus, when the semiconductor element is disposed on the element contact, the semiconductor element is elevated, and the distance between the upper surface of the substrate passivation layer and the lower surface of the semiconductor element is increased, and applicable varieties of molding compound for packaging the semiconductor element increase, and the selectivity of the molding compound becomes more flexible. In addition, during the molding process, the molding compound in liquid state can smoothly flow into the gap between the upper surface of the substrate passivation layer and the lower surface of the semiconductor element, hence increasing the filling quality of the molding compound between the substrate and the semiconductor element.

While the invention has been described by way of example and in terms of an embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor package, comprising:
a substrate comprising a substrate passivation layer, and a substrate pad, wherein the substrate pad comprises a protrusion projecting from the substrate passivation layer and an embedded portion embedded in the substrate passivation layer;
a semiconductor element comprising an under bump metallurgy (UBM), wherein the UBM defines a recess, and the ratio of a width of the recess to a first width of the protrusion is larger than or substantially equal to 1;
an element contacts connecting the UBM and the substrate pad; and
a molding compound covering the semiconductor element.

2. The semiconductor package according to claim 1, wherein a portion of the molding compound is disposed between the semiconductor element and the substrate.

3. The semiconductor package according to claim 1, wherein the substrate comprises a base, and the embedded portion comprises:
a bottom portion disposed on the base; and
a connection portion connecting the protrusion and the bottom portion.

4. The semiconductor package according to claim 3, wherein the ratio of the first width of the protrusion to a second width of the connection portion ranges between from 0.3 to 1.5.

5. The semiconductor package according to claim 3, wherein the protrusion, the connection portion and the bottom portion form an I-shaped structure.

6. The semiconductor package according to claim 3, wherein the second width of the connection portion is larger than the first width of the protrusion and the width of the bottom portion as well.

7. The semiconductor package according to claim 3, wherein the second width of the connection portion, the first width of the protrusion and the width of the bottom portion are substantially identical.

8. The semiconductor package according to claim 3, wherein an aperture is defined by the substrate passivation layer and filled with the embedded portion.

9. The semiconductor package according to claim 1, wherein the substrate pad is made from copper.

10. The semiconductor package according to claim 1, wherein the lower surface of the semiconductor element and the upper surface of the substrate passivation layer are separated by a distance, and the ratio of the height of the protrusion to the distance is smaller than or substantially equal to 0.5.

11. The semiconductor package according to claim 1, wherein the semiconductor element comprises an element pad, the UBM comprises an inner-layer structure and an outer-layer structure connected to the inner-layer structure, and the inner-layer structure is disposed on the substrate pad.

12. The semiconductor package according to claim 1, wherein the ratio of the width of the recess to the first width of the protrusion is larger than or substantially equal to 1.2.

13. The semiconductor package according to claim 1, wherein the molding compound has a plurality of fillers, and the size of the maximum filler ranges from 18 to 23 micrometers (μm).

14. The semiconductor package according to claim 13, wherein the lower surface of the semiconductor element and the upper surface of the substrate passivation layer are separated by a distance, and the difference between the distance and the size of the maximum filler is at least larger than 5 μm.

15. The semiconductor package according to claim 1, wherein the height of the protrusion is smaller than 25 μm.

16. The semiconductor package according to claim 1, wherein the element contacts connect the UBM and the protrusion.

17. The semiconductor package according to claim 1, wherein the element contacts at most covers the UBM and the protrusion.

18. The semiconductor package according to claim 17, wherein the UBM comprises an inner-layer structure and an outer-layer structure connected to the inner-layer structure, and the element contacts merely covers the outer-layer structure of the UBM.

19. The semiconductor package according to claim 1, wherein the element contact is a solder ball, a bump or a conductive pillar.

20. The semiconductor package according to claim 19, wherein the conductive pillar is a copper pillar.
